(19) United States
(12) Patent Application Publication
(10) Pub. No.: US 2025/0110169 A1
(43) Pub. Date: Apr. 3, 2025

(54) SYSTEMS AND METHODS FOR LOCATING ELECTRICAL FAULTS

(71) Applicant: The ADT Security Corporation, Boca Raton, FL (US)

(72) Inventor: Karl William WIANT II, Pelzer, SC (US)

(21) Appl. No.: 18/478,176

(22) Filed: Sep. 29, 2023

(51) Int. Cl. G01R 31/08; H02H 1/00

(52) U.S. Cl. CPC G01R 31/088; H02H 1/0007

(57) ABSTRACT

A system and method are described. An example system embodiment includes a controller configured to receive a fault detection signal from an outlet of a plurality of outlets indicating detection of a fault; in response to the fault detection signal, configure each of the outlets to be in the open state; cause individual ones of the outlets to transition from the open to the closed state one at a time until an additional fault occurs; determine a location of the additional fault based on an identity of a first outlet configured in the open state and transitioned to the closed state prior to the additional fault occurring; determine a corrective state for each of the outlets; cause each of the outlets to be in the corrective state determined for each of the outlets; and transmit a notification based on the location of the additional fault.

### TECHNICAL FIELD

The present technology is generally related to detecting and locating electrical faults.

### BACKGROUND

Electrical faults are a risk in any electrical system. Electrical faults result from numerous causes, such as but not limited to wiring issues, aging wiring, environmental factors (e.g., humidity, temperature), power surges, and equipment failure. Electrical faults can carry severe risks of fire, electrical shock, power outages, and damage to equipment and infrastructure. Many electrical systems use combinations of circuit breakers, fuses, and interrupters (such as, e.g., Ground Fault Circuit Interrupters (GFCIs)) to mitigate the risks associated with electrical faults.

### BRIEF DESCRIPTION OF THE DRAWINGS

A more complete understanding of the present disclosure, and the attendant advantages and features thereof, will be more readily understood by reference to the following detailed description when considered in conjunction with the accompanying drawings wherein:

FIG. 1 is a diagram of an example system according to some embodiments of the present disclosure;

FIG. 2 is a block diagram of an example of a controller and outlet in the system of FIG. 1 according to some embodiments of the present disclosure;

FIG. 3 is a flowchart of an example process performed in the system of FIG. 1 according to some embodiments of the present disclosure;

FIG. 4 is a flowchart of another example process performed in the system of FIG. 1 according to some embodiments of the present disclosure; and

FIG. 5 is a block diagram of an example of an outlet in the system of FIG. 1 according to some embodiments of the present disclosure.

### DETAILED DESCRIPTION

As used herein, relational terms, such as “first” and “second,” “top” and “bottom,” and the like, may be used solely to distinguish one entity or element from another entity or element without necessarily requiring or implying any physical or logical relationship or order between such entities or elements. The terminology used herein is for the purpose of describing particular embodiments only and is not intended to be limiting of the concepts described herein. As used herein, the singular forms “a”, “an” and “the” are intended to include the plural forms as well, unless the context clearly indicates otherwise. The terms “comprises,” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

In embodiments described herein, the joining term, “in communication with” and the like, may be used to indicate electrical or data communication, which may be accomplished by physical contact, induction, electromagnetic radiation, radio signaling, infrared signaling or optical signaling, for example. Multiple components may interoperate and modifications and variations are possible to achieve the electrical and data communication.

In some embodiments described herein, the term “coupled,” “connected,” and the like, may be used herein to indicate a connection, although not necessarily directly, and may include wired and/or wireless connections.

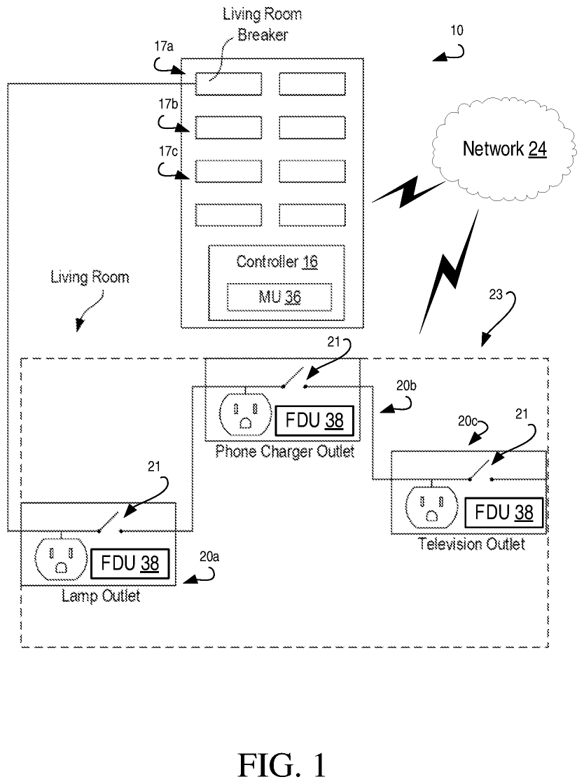

Referring to the drawing figures, in which like elements are referred to by like reference numerals, there is shown in FIG. 1 a diagram of an example system 10 comprising a controller 16. The controller 16 is in communication with one or more circuit breakers 17a-17c (collectively referred to as circuit breakers 17). The controller 16 is configured for controlling and/or managing of aspects of the system 10. For example, controller 16 comprises monitoring unit 36, which may be configured to perform various functionalities associated with the system 10, including those described herein. Further, controller 16 can be in simultaneous communication and/or configured to separately communicate with one or more outlets 20a-20c (collectively referred to as outlets 20) and/or a network 24. While only outlets 20a-20c are shown in FIG. 1, the teachings described herein are equally applicable to systems with more than three outlets 20. By way of the network 24, controller 16 may be in communication with a user device, such as a display device, mobile device and/or tablet, and/or a premises monitoring system. According to various embodiments, the premises monitoring system may be or include, for example, a home alarm system, a home automation system, or other types of monitoring systems.

Each outlet 20 is configured to receive one or more conductors (e.g., a mating plug) of one or more electrical devices to thereby provide power to one or more electrical devices. The outlet 20 includes a fault detection unit 38 configured to detect an electrical fault. The outlet 20 also includes a switch 21 that can be operated to open and close a circuit 23 that is used to power the electrical equipment. For example, when switch 21 of outlet 20b is open, outlet 20b is in an open state where power is no longer provided on the load side of outlet 20b but outlet 20b continues to provide power, if power is received from the line side of outlet 20b. When switch 21 of outlet 20b is closed, outlet 20b is in a closed state where power is provided to the load side of outlet 20b, i.e., power is provided to outlet 20c in this example, and outlet 20b continues to provide power, if power is received from the line side of outlet 20b.

One or more outlets 20 may be in electrical communication with each other to form a circuit 23. Though only one circuit 23 is depicted in FIG. 1, the system 10 may include more than one circuit 23, each including one or more outlets 20.

As noted above, system 10 may include network 24 (which may refer to one or more networks 24), which may be configured to provide direct and/or indirect communication, e.g., wired and/or wireless communication, between any two or more components of system 10, e.g., controller 16 and outlet 20. In a non-limiting example, controller 16 may communicate with the outlet 20 via network 24, e.g., to determine the identity of outlets 20, learn which outlets 20 are associated with which circuit 23, and to communicate regarding the detection of a fault and perform actions related thereto. Although network 24 is shown as an intermediate network between components/devices of system 10, any component or device may communicate directly with any other component/device of system 10. Such communication may be wired (e.g., via a powerline) and/or wireless and may be, e.g., via a ZigBee based communication link (e.g., a network based on Institute of Electrical and Electronics Engineers (IEEE) protocols), a Z-wave based communication link, over a local area network, (e.g., a network-based on IEEE protocols), and/or a low power and short distance communication protocol (e.g., Wi-Fi, Dect Ultra Low Energy (Dect/ULE), or Bluetooth®).

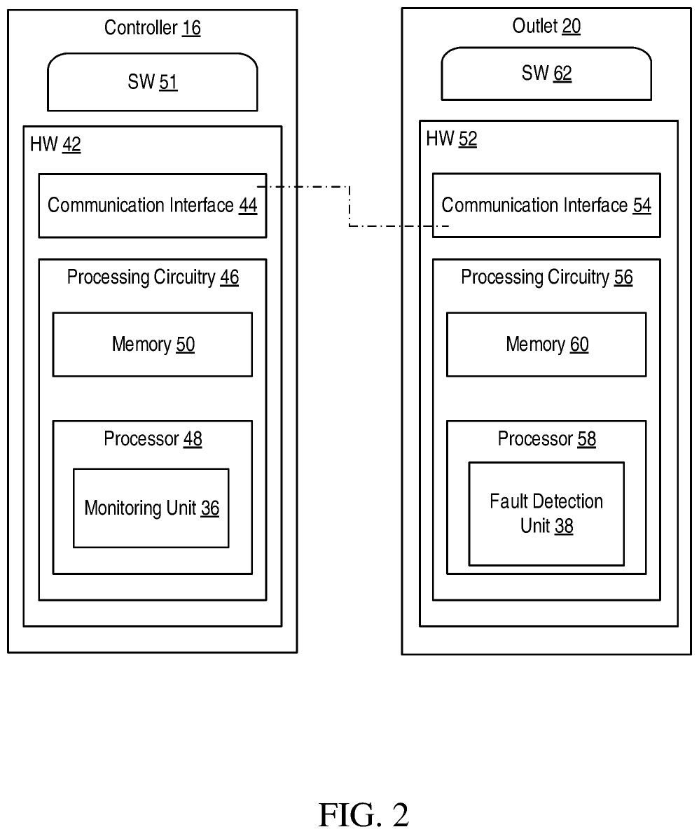

Example implementations, in accordance with embodiments of system 10 discussed in the preceding paragraphs will now be described with reference to FIG. 2. The controller 16 includes hardware 42. The hardware 42 may include processing circuitry 46. The processing circuitry 46 may include a processor 48 and a memory 50. In addition to or instead of a processor 48, the processing circuitry 46 may comprise integrated circuitry for processing and/or control, e.g., one or more processors and/or processor cores, field programmable gate arrays (FPGAs), and/or application specific integrated circuits (ASICs) adapted to execute instructions. The processor 48 may be configured to access (e.g., write to and/or read from) the memory 50, which may comprise any kind of volatile and/or nonvolatile memory, e.g., cache, buffer memory, random access memory (RAM), read-only memory (ROM), optical memory, and/or erasable programmable read-only memory (EPROM). Further, memory 50 may be configured as a storage device. The processing circuitry 46 may be configured to perform various functionality described herein. For example, computer instructions may be stored in memory 50 and/or another computer-readable medium that, when executed by the processor 48, cause the processor 48 to perform various functionality.

Hardware 42 of controller 16 may include communication interface 44 enabling controller 16 to communicate with any component or device of system 10. For example, communication interface 44 may be configured for establishing and maintaining at least a wireless or wired connection with any component or device of system 10, such as outlet 20, etc. The communication interface 44 may be formed as or may include, for example, one or more radio frequency (RF) transmitters, one or more RF receivers, and/or one or more RF transceivers.

Controller 16 further has software 51 stored internally in, for example, memory 50, or stored in external memory (e.g., database, storage array, network storage device, etc.) accessible by the controller 16 via an external connection. Software 51 may include any software or program configured to perform the steps or processes of the present disclosure, e.g., providing an interface for a user to provide an input to the controller 16 and/or receive an output from the controller 16. Further, software 51 may run and/or be included directly as part of controller 16. Software 51 may be virtualized and/or running outside controller 16 and/or any of the components thereof.

The processing circuitry 46 may be configured to control any of methods and/or processes described herein and/or to cause such methods, and/or processes to be performed, e.g., by controller 16. Processor 48 corresponds to one or more processors 48 for performing controller 16 functions described herein. The memory 50 is configured to store data and/or files such as system data and/or other information/data described herein. In some embodiments, the software 51 may include instructions that, when executed by the processor 48 and/or processing circuitry 46, causes the processor 48 and/or processing circuitry 46 to perform the processes described herein with respect to controller 16. For example, processing circuitry 46 of the controller 16 may include monitoring unit 36, which may be configured to perform any of the processes, steps, or functions described herein.

The outlet 20 includes hardware 52. The hardware 52 may include processing circuitry 56. The processing circuitry 56 may include a processor 58 and a memory 60. In addition to or instead of a processor 58, the processing circuitry 56 may comprise integrated circuitry for processing and/or control, e.g., one or more processors and/or processor cores, FPGAs, and/or ASICs adapted to execute instructions. The processor 58 may be configured to access (e.g., write to and/or read from) the memory 60, which may comprise any kind of volatile and/or nonvolatile memory, e.g., cache, buffer memory, RAM, ROM, optical memory, and/or EPROM. Further, memory 60 may be configured as a storage device. The processing circuitry 56 may be configured to perform various functionality described herein. For example, computer instructions may be stored in memory 60 and/or another computer-readable medium that, when executed by the processor 58, cause the processor 58 to perform various functionality.

Hardware 52 of outlet 20 may include communication interface 54 enabling outlet 20 to communicate with any component or device of system 10. For example, communication interface 54 may be configured for establishing and maintaining at least a wireless or wired connection with any component or device of system 10, such as controller 16, etc. The communication interface 54 may be formed as or may include, for example, one or more RF transmitters, one or more RF receivers, and/or one or more RF transceivers.

Outlet 20 further has software 62 stored internally in, for example, memory 60. Software 62 may include any software or program configured to perform the steps or processes of the present disclosure, e.g., providing an interface for a user to provide an input to the outlet 20 and/or receive an output from the outlet 20. Further, software 62 may run and/or be included directly as part of controller 16.

The processing circuitry 56 may be configured to control any of methods and/or processes described herein and/or to cause such methods, and/or processes to be performed, e.g., by outlet 20. Processor 58 corresponds to one or more processors 48 for performing outlet 20 functions described herein. The memory 60 is configured to store data and/or files such as system data and/or other information/data described herein. In some embodiments, the software 62 may include instructions that, when executed by the processor 58 and/or processing circuitry 56, causes the processor 58 and/or processing circuitry 56 to perform the processes described herein with respect to outlet 20. For example, processing circuitry 56 of the outlet 20 may include fault detection unit 38, which may be configured to perform any of the processes, steps, or functions described herein.

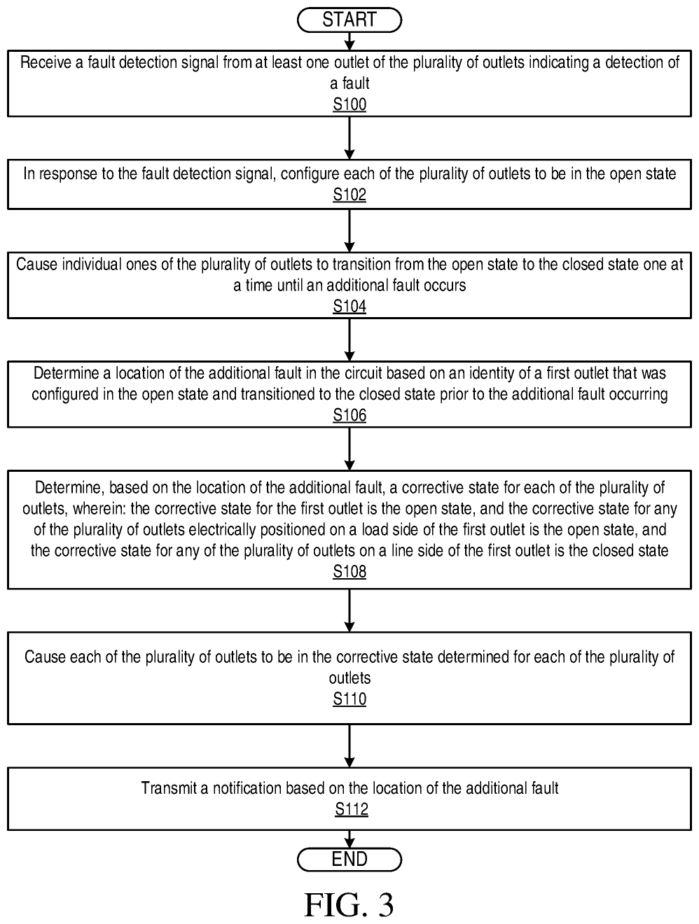

FIG. 3 is a flowchart of an example process in controller 16 of system 10 according to some embodiments of the present disclosure. One or more blocks described herein may be performed by one or more elements of controller 16, such as by one or more of processing circuitry 46 (including the monitoring unit 36) and/or processor 48 and/or communication interface 44. System 10 comprises a plurality of outlets 20 in electrical communication with each other and with controller 16, where the plurality of outlets 20 are configured to form a circuit 23. Each outlet 20 of the plurality of outlets 20 is configured to have a respective associated identity and a relative position in the circuit 23, and each outlet of the plurality of outlets 20 is configured to be in an open state or a closed state.

Controller 16 is configured to receive a fault detection signal from at least one outlet 20 of the plurality of outlets 20 indicating a detection of a fault (Block S100), as described herein. Controller 16 is configured to, in response to the fault detection signal, configure each of the plurality of outlets 20 to be in the open state (Block S102). Controller 16 is configured to cause individual ones of the plurality of outlets 20 to transition from the open state to the closed state one at a time until an additional fault occurs (Block S104), as described herein.

Controller 16 is configured to determine a location of the additional fault in the circuit 23 based on an identity of a first outlet 20 that was configured in the open state and transitioned to the closed state prior to the additional fault occurring (Block S106), as described herein. Controller 16 is configured to determine, based on the location of the additional fault, a corrective state for each of the plurality of outlets 20, wherein: the corrective state for the first outlet 20 is the open state; the corrective state for any of the plurality of outlets 20 electrically positioned on a load side of the first outlet 20 is the open state; and

the corrective state for any of the plurality of outlets on a line side of the first outlet is the closed state (Block S108), as described herein. Controller 16 is configured to cause each of the plurality of outlets to be in the corrective state determined for each of the plurality of outlets (Block S110), as described herein. Controller 16 is configured to transmit a notification based on the location of the additional fault (Block S112), as described herein.

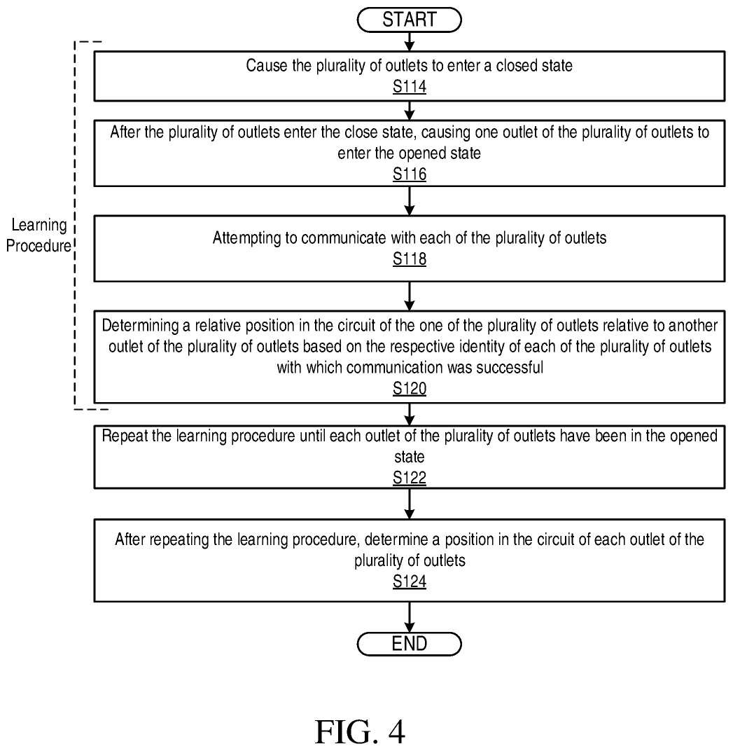

FIG. 4 is a flowchart of an example process in controller 16 of system 10 according to some embodiments of the present disclosure. One or more blocks described herein may be performed by one or more elements of controller 16, such as by one or more of processing circuitry 46 (including the monitoring unit 36) and/or processor 48 and/or communication interface 44.

Controller 16 is configured to cause (Block S114) the plurality of outlets 20 to enter a closed state, as described herein. Controller 16 is configured to, after the plurality of outlets enter the closed state, cause (Block S116) one outlet of the plurality of outlets to enter the opened state, as described herein. Controller 16 is configured to attempt (Block S116) to attempt to communicate with each of the plurality of outlets, as described herein. Controller 16 is configured to determine (Block S120) a relative position in the circuit of the one of the plurality of outlets relative to another outlet of the plurality of outlets based on the respective identity of each of the plurality of outlets with which communication was successful, as described herein. Controller 16 is further configured to repeat (Block S122) the learning procedure until each outlet of the plurality of outlets has been in the opened state, as described herein. Controller 16 is further configured to, after repeating the learning procedure, determine (Block S124) a position in the circuit 23 of each outlet 20 of the plurality of outlets 20, as described herein.

Having described the general process flow of arrangements of the disclosure and having provided examples of hardware and software arrangements for implementing the processes and functions of the present disclosure, the sections below provide details and examples of arrangements for detecting and locating electrical faults. One or more controller 16 functions described below may be performed by one or more of processing circuitry 46, processor 48, monitoring unit 36, etc. One or more outlet 20 functions described below may be performed by one or more of processing circuitry 56, processor 58, fault detection unit 38.

An example embodiment relates to detecting and locating electrical faults, such as arc faults, that can cause fires, in premises wiring systems. A controller 16 in an electrical panel communicates with an outlet 20, such as but not limited to a “smart” electrical outlet, on a circuit 23 and instructs those outlets 20 to enter an close state and sequentially open the circuit (such as by operation of a switch 21 to enter a close state) at their respective locations for the controller 16 to learn the relative positions of the outlets 20 on the circuit 23, as described below and with respect to FIG. 4. Thereafter, the outlets 20 can monitor the electrical system at their respective locations and detect a fault, such as via the fault detection unit 38. When a fault is detected and/or its location determined, the controller 16 can notify a user of the fault and identify where in the circuit 23 the fault occurred. Controller 16 providing the location of the fault can help streamline troubleshooting and repairs of a dangerous situation.

An example embodiment includes an electrical panel and one or more outlets 20, e.g., “smart” outlets. An example of an electrical panel may be according to that illustrated in FIG. 1. The electrical panel can include a controller 16, circuit breakers 17, and/or other components.

The controller 16 may be configured to communicate with the circuit breakers 17 in the panel (e.g., to command them to turn off or on), the electrical outlets 20 described below (e.g., to command them to open or close internal switches 21), and a user application on a smart phone accessible via, e.g., the network 24. The controller 16 can communicate with the outlet 20 and circuit breakers 17 through signals (e.g., power status signals indicating power outlets, notification signals, command signals, etc.) over the electrical wiring and/or wirelessly via communication interface 44.

The circuit breakers 17 may be configured to open or close in response to commands from the controller 16. That is, the circuit breaker 17 may have an internal circuit that is switchable to/from an open state (i.e., open circuit) from/to a closed state (closed circuit).

In at least one embodiment, functionality performed by controller 16 can be performed using an alarm panel, smart home hub, or other device in system 10 or a premises monitoring system.

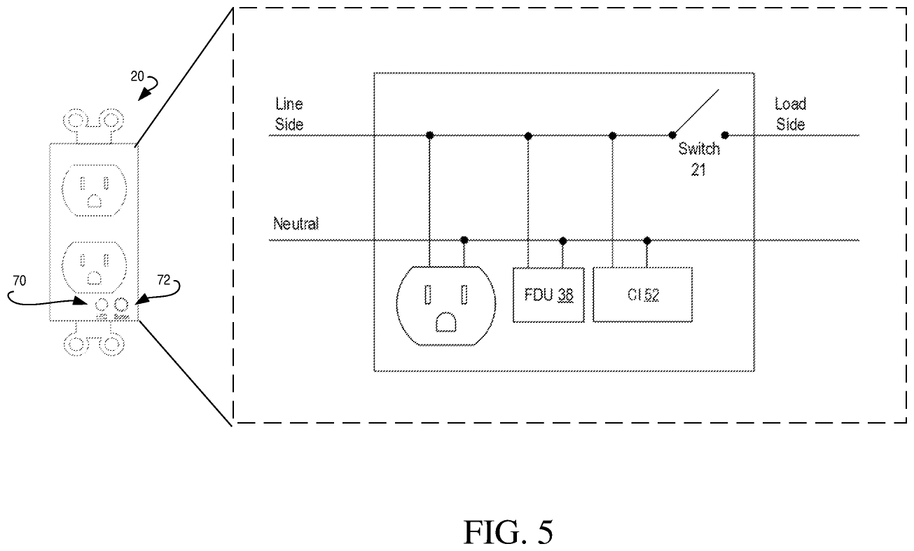

An example of an outlet 20, e.g., a “smart” outlet, is illustrated in FIG. 5. As shown in FIG. 5, the outlet 20 can include a light-emitting diode (“LED”) 70 that is used to indicate the outlet status. The LED 70 can indicate, for example, that the outlet 20 is in a learning mode (corresponding to the controller 16 performing a learning procedure to “learn” the relative physical and/or electrical location of the outlet), that the outlet 20 and/or circuit 23 is operating normally, or that a fault has been detected. The outlet 20 can also include a button 72 that a user can press to control various aspects of the outlet 20. For example, a user can press the button 72 to initiate a pairing procedure with the controller 16 in the electrical panel or to reset the outlet 20 after an issue has been resolved.

The right portion of FIG. 5 depicts a functional block diagram of an outlet 20. The outlet 20 can include a fault detector (also referred to as fault detector circuit) that may be part of a fault detection unit 38, a transceiver (e.g., communication interface 54), and a switch 21. The fault detector can monitor voltage, current, and/or other parameters associated with the outlet 20 to determine whether a fault condition exists. A fault condition can occur when an arc fault, ground fault, or other anomaly is detected by the fault detector. The outlet 20 can also include a transceiver for communication with the controller 16 in the electrical panel and/or other devices. The switch 21 can be opened or closed in response to commands from the controller 16 in the electrical panel. When the switch 21 of outlet 20 is open, other outlets 20, electrical switches (e.g., wall switches), light fixtures, etc. coupled to the load side of outlet 20 will not receive power from their respective line side. In this example, the other outlets 20 may not be able to receive and/or respond to communications from controller 16 as these outlets 20 are without power. When the switch 21 of outlet 20 is closed, other outlets 20, switches (e.g., wall switches), light fixtures, etc. coupled to the load side of the outlet 20 will receive power from their respective line side (e.g., so long as power is being provided to the outlet 20). In this example, the other outlets 20 may be able to receive and/or respond to communications from controller 16 as these outlets 20 receive power from the line side, which may power the respective transmitters and/or receivers of these outlets 20.

Operation of an example embodiment, which may be similar to the system 10 of FIG. 1, is as follows. Operation of the system may involve (1) the controller 16 learning the positions of the outlets 20 relative to each other in the circuit 23; and (2) monitoring for faults and taking responsive action.

Another example process of the controller 16 learning the positions of the outlets 20 relative to each other involves one or more of the following steps. The outlets 20 are installed and configured to communicate with the controller 16 using, for example, communication interface 54. For example, a homeowner or electrician may install the outlets 20 and configure the outlets to access network 24 to communicate with the controller 16.

Next, each outlet 20 is configured with a name, e.g., user-friendly name. In this example, the user-friendly names for the outlets are “Phone Charger Outlet,” “Television Outlet,” and “Lamp Outlet” (indicating what is plugged into the outlets 20). Quick-response code (“QR codes”) on the outlets 20 can be scanned to facilitate assigning user-friendly names to the outlets 20. The configured names may be stored in memory 60 and/or memory 50.

Next, the controller 16 in the electrical panel turns off all breakers 17 to the premises, except for the breaker 17 for the circuit 23 for the outlets 20. So, in this particular example, all breakers 17 are off, except for the living room breaker 17.

As part of a learning procedure, the controller 16 then sends commands to the outlets 20 so that the switches 21 in the Lamp and Television outlets 20a, 20c are closed and the switch 21 in the Phone Charger outlet 20b is open. This will cause the Television outlet 20c to lose power since the line side of Television outlet 20c is connected to Phone Charger outlet 20b, such that Television outlet 20c not be able to communicate with the controller 16. For example, communication interface 54 of Television outlet 20c may have no power such that Television outlet 20c is not able to communicate with the controller 16.

The controller 16 will then determine which outlets 20 are powered on and which ones are powered off by attempting to communicate with the outlets 20. In this example, the controller 16 will be able to communicate with (e.g., receive a signal from, such as in response to a ping) the Lamp outlet 20a and the Phone Charger outlet 20b, but the Television outlet 20c will be offline. Therefore, the controller 16 can determine that the Television outlet 20c is on the load side (i.e., is “downstream”) relative to the Phone Charger outlet 20b and the Lamp outlet 20a. The controller 16 will then send a command to the Phone Charger outlet 20b to close its switch 21 (so that the Television outlet 20c will receive power via Phone Charger outlet 20b).

The controller 16 may repeat the learning procedure using another outlet 20 of the plurality of outlets 20 (e.g., 20a-20c) in place of the first outlet 20. For example, the controller 16 will then send commands to the outlets 20 to cause the Television outlet's 20c switch 21 to be open and the other outlets' 20 switches 21 to be closed.

Then, the controller 16 will determine which outlets 20 it is able to communicate with and which ones are offline. In this example, the controller 16 will be able to communicate with all the outlets 20. Therefore, the controller 16 can determine that there are no outlets 20 connected directly or indirectly to the load side of the Television outlet 20c. The controller 16 will then send a command to the Television outlet 20c to close its switch.

The controller 16 may repeat the learning procedure by, for example, sending commands to the outlets 20 to cause the Lamp outlet's 20a switch 21 to open and the other outlet's 20 switches 21 to close.

The controller 16 will then determine which outlets 20 it is able to communicate with and which ones are offline. In this example, the controller 16 will be able to communicate with the Lamp outlet 20a, but not the Phone Charger 20b or Television outlets 20c (because they are offline). Therefore, the controller 16 can determine that the Phone Charger outlet 20b and the Television outlet 20c are connected to the load side of the Lamp outlet 20a.

From the example process above, the controller 16 can determine that the relative order (e.g., electrical communication order) of the outlets beginning from the outlet nearest the electrical panel is the Lamp Outlet 20a, followed by the Phone Charger Outlet 20b, followed by the Television Outlet 20c.

In one or more embodiments, controller 16 may be configured to create a logical tree structure of the outlets 20 to determine the relative physical and/or electrical location of the outlets 20. For example, using the process above, a parent node (e.g., outlet 20) in the logical tree structure is determined to be on the line side of a child node (e.g., outlet 20) and a child node is determined to be on the load side of a parent node. Hence, which one or more outlets 20 are commanded to open and which one or more outlets 20 are commended to close may be based on the current logical tree structure created and/or being created by controller 16.

After the controller 16 has determined the relative locations of the outlets 20, the controller 16 can instruct the outlets 20 to begin the monitoring process. This can involve the following steps. First, the fault detectors in the outlets 20 (e.g., as part of the fault detection unit 38) begin monitoring current, voltage, or other parameters to determine whether there is an anomalous condition. If a fault detector detects a fault (e.g., related to the anomalous condition), the fault detector notifies the controller 16 and includes information identifying the particular outlet 20 that detected the fault. For example, the information may include the name of the outlet, type of fault, time the fault was detected (i.e., timestamp data), duration of fault, voltage and/or current amplitudes before, during and/or after the fault, etc.

The controller 16 can use the information about the detected faults to identify the relative location of the fault. For example:

If the Phone Charger 20b and Television outlets 20c detect a fault, but the Lamp outlet 20a does not detect a fault, the controller 16 can determine that the fault occurred between the Phone Charger outlet 20b and Television outlets 20c.

If a fault is detected by all outlets 20, the controller 16 can compare information from the outlets 20 (e.g., voltage or current amplitudes) to determine the fault location. Alternatively, the controller 16 can sequentially turn on the outlets' 20 switches 21 in order until the fault is detected. In at least one embodiment, this may involve a manual command from a user received, by controller 16, from the device application operating on a wireless device. An example scenario involves the main breaker tripping due to a fault. The user launches a device application, such as a smart phone application, to use a diagnostic mode. The application may cause the system 10 to turn on the outlets 20 one at a time until the fault occurs again. This may facilitate the system 10 (e.g., via the controller 16) determining that the first outlet 20 is linked to the fault.

After the location of the fault is determined, the controller 16 can send a message to an application on the user's device, e.g., smartphone, notifying the user of the determined fault location. In some embodiments, the notification may include the identity of the outlet(s) 20 proximate to the fault. In some embodiments, the controller 16 may turn off the circuit breaker 17 and/or one or more outlets 20 after the diagnostic process, so that the user needs to manually turn on the breaker 17 and/or reset the outlets 20.

In at least one embodiment, the controller 16 can determine a corrective state for each of the outlets. The corrective state of each outlet 20 may collectively isolate, mitigate, and/or avoid re-occurrence of the fault. The corrective states of the outlets 20 may be such that one or more outlets 20 configured to enter an open state (such as, e.g., those outlets 20 associated with the fault), and one or more outlets 20 may be configured to enter a closed state and can continue powering any corresponding devices. The controller 16 may activate or deactivate switch 21 such that the state of each of the outlets 20 (i.e., in one of the open stated or closed state) corresponds to a corrective state determined for the respective outlet 20.

The concepts described herein may be embodied as a method, data processing system, computer program product and/or computer storage media storing an executable computer program. Accordingly, the concepts described herein may take the form of an entirely hardware embodiment, an entirely software embodiment or an embodiment combining software and hardware aspect. Any process, step, action and/or functionality described herein may be performed by, and/or associated to, a corresponding module, which may be implemented in software and/or firmware and/or hardware. Furthermore, the disclosure may take the form of a computer program product on a tangible computer usable storage medium having computer program code embodied in the medium that can be executed by a computer. Any suitable tangible computer readable medium may be utilized including hard disks, CD-ROMs, electronic storage devices, optical storage devices, or magnetic storage devices.

Some embodiments are described herein with reference to flowchart illustrations and/or block diagrams of methods, systems and computer program products. Each block of the flowchart illustrations and/or block diagrams, and combinations of blocks in the flowchart illustrations and/or block diagrams, can be implemented by computer program instructions. These computer program instructions may be provided to a processor of a general purpose computer (to thereby create a special purpose computer), special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable memory or storage medium that can direct a computer or other programmable data processing apparatus to function in a particular manner, such that the instructions stored in the computer readable memory produce an article of manufacture including instruction means which implement the function/act specified in the flowchart and/or block diagram block or blocks.

The computer program instructions may also be loaded onto a computer or other programmable data processing apparatus to cause a series of operational steps to be performed on the computer or other programmable apparatus to produce a computer implemented process such that the instructions which execute on the computer or other programmable apparatus provide steps for implementing the functions and/or acts specified in the flowchart and/or block diagram block or blocks.

The functions and acts noted in the blocks may occur out of the order noted in the operational illustrations. For example, two blocks shown in succession may in fact be executed substantially concurrently or the blocks may sometimes be executed in the reverse order, depending upon the functionality and/or acts involved. Although some of the diagrams include arrows on communication paths to show a primary direction of communication, it is to be understood that communication may occur in the opposite direction to the depicted arrows.

Computer program code for carrying out operations of the concepts described herein may be written in an object-oriented programming language such as Python, Java® or C++. However, the computer program code for carrying out operations of the disclosure may also be written in conventional procedural programming languages, such as the “C” programming language. The program code may execute entirely on the user's computer, partly on the user's computer, as a stand-alone software package, partly on the user's computer and partly on a remote computer or entirely on the remote computer. In the latter scenario, the remote computer may be connected to the user's computer through a local area network (LAN) or a wide area network (WAN), or the connection may be made to an external computer (for example, through the Internet using an Internet Service Provider).

Many different embodiments have been disclosed herein, in connection with the above description and the drawings. It would be unduly repetitious and obfuscating to literally describe and illustrate every combination and subcombination of these embodiments. Accordingly, all embodiments can be combined in any way and/or combination, and the present specification, including the drawings, shall be construed to constitute a complete written description of all combinations and subcombinations of the embodiments described herein, and of the manner and process of making and using them, and shall support claims to any such combination or subcombination.

In addition, unless mention was made above to the contrary, the accompanying drawings are not to scale. A variety of modifications and variations are possible in light of the above teachings without departing from the scope and spirit of the present disclosure.

What is claimed is:

1. A system, comprising:
a plurality of outlets in electrical communication with each other, the plurality of outlets configured to form a circuit, each outlet of the plurality of outlets configured to have a respective associated identity and a relative position in the circuit, each outlet of the plurality of outlets being configured to be in an open state or a closed state;
a controller in communication with the plurality of outlets, the controller comprising at least one processor and at least one computer-readable storage medium comprising a plurality of instructions that, when executed by the at least one processor, cause the at least one processor to:
receive a fault detection signal from at least one outlet of the plurality of outlets indicating a detection of a fault;
in response to the fault detection signal, configure each of the plurality of outlets to be in the open state;
cause individual ones of the plurality of outlets to transition from the open state to the closed state one at a time until an additional fault occurs;
determine a location of the additional fault in the circuit based on an identity of a first outlet that was configured in the open state and transitioned to the closed state prior to the additional fault occurring;
determine, based on the location of the additional fault, a corrective state for each of the plurality of outlets, wherein:
the corrective state for the first outlet is the open state;
the corrective state for any of the plurality of outlets electrically positioned on a load side of the first outlet is the open state; and
the corrective state for any of the plurality of outlets on a line side of the first outlet is the closed state;
cause each of the plurality of outlets to be in the corrective state determined for each of the plurality of outlets; and
transmit a notification based on the location of the additional fault.

2. The system of claim 1, wherein the plurality of instructions are further configured to cause the at least one processor to:
perform a learning procedure comprising:
causing the plurality of outlets to enter a closed state;
after the plurality of outlets enter the closed state, causing one outlet of the plurality of outlets to enter the opened state;
attempting to communicate with each of the plurality of outlets; and
determining a relative position in the circuit of the one of the plurality of outlets relative to another outlet of the plurality of outlets based on the respective identity of each of the plurality of outlets with which communication was successful;
repeat the learning procedure until the relative position of each of the plurality of outlets has been determined.

3. A system, comprising:
a controller configured to communicate with a plurality of outlets that are configured to form a circuit, the controller comprising at least one processor and at least one computer-readable storage medium comprising a plurality of instructions that, when executed by the at least one processor, cause the at least one processor to:
receive, from at least one outlet of the plurality of outlets, a fault detection signal indicating a detection of a fault;
in response to the fault detection signal, cause each of the plurality of outlets to be in an open state;
cause individual ones of the plurality of outlets to transition from the open state to a closed state one at a time until an additional fault occurs;
determine a location of the additional fault in the circuit based on a first outlet of the plurality of outlets that was configured in the open state and transitioned to the closed state prior to the additional fault occurring; and
perform at least one action based on the location of the fault.

4. The system of claim 3, wherein the fault detection signal is associated with a fault detector circuit in at least one of the plurality of outlets.

5. The system of claim 3, wherein the at least one action comprises:
determining a corrective state for each of the plurality of outlets; and
causing each of the plurality of outlets to be in the corresponding corrective state.

6. The system of claim 5, wherein the corrective state for the first outlet is the open state.

7. The system of claim 6, wherein at least one outlet of the plurality of outlets is electrically positioned on a line side of the first outlet, and the corrective state for each of the at least one outlet is the closed state.

8. The system of claim 6, wherein at least one outlet of the plurality of outlets is electrically positioned on a load side of the first outlet, and the corrective state for each of the at least one outlet is the open state.

9. The system of claim 3, wherein the at least one action comprises transmitting a notification that indicates the location of the additional fault.

10. The system of claim 3, wherein the plurality of instructions is further configured to cause the at least one processor to:
perform a learning procedure comprising:
cause the plurality of outlets to enter a closed state;
after the plurality of outlets enter the close state, causing one outlet of the plurality of outlets to enter the opened state;
attempting to communicate with each of the plurality of outlets; and
determining a relative position in the circuit of the one of the plurality of outlets relative to another outlet of the plurality of outlets based on a respective identity of each of the plurality of outlets with which communication was successful.

11. The system of claim 10, wherein the plurality of instructions is further configured to cause the at least one processor to:
repeat the learning procedure until each outlet of the plurality of outlets have been in the opened state; and
after repeating the learning procedure, determine a position in the circuit of each outlet of the plurality of outlets.

12. A method implemented by a system, the system comprising a controller configured to communicate with a plurality of outlets that are configured to form a circuit, the method comprising:
receiving, from at least one outlet of the plurality of outlets, a fault detection signal indicating a detection of a fault;
in response to the fault detection signal, causing each of the plurality of outlets to be in an open state;
causing individual ones of the plurality of outlets to transition from the open state to a closed state one at a time until an additional fault occurs;
determining a location of the additional fault in the circuit based on a first outlet of the plurality of outlets that was configured in the open state and transitioned to the closed state prior to the additional fault occurring; and
performing at least one action based on the location of the fault.

13. The method of claim 12, wherein the fault detection signal is associated with a fault detector circuit in at least one of the plurality of outlets.

14. The method of claim 12, wherein the at least one action comprises:
determining a corrective state for each of the plurality of outlets; and
causing each of the plurality of outlets to be in the corresponding corrective state.

15. The method of claim 14, wherein the corrective state for the first outlet is the open state.

16. The method of claim 15, wherein at least one outlet of the plurality of outlets is electrically positioned on a line side of the first outlet, and the corrective state for each of the at least one outlet is the closed state.

17. The method of claim 15, wherein at least one outlet of the plurality of outlets is electrically positioned on a load side of the first outlet, and the corrective state for each of the at least one outlet is the open state.

18. The method of claim 12, wherein the at least one action comprises transmitting a notification that indicates the location of the additional fault.

19. The method of claim 12, further comprising:
performing a learning procedure comprising:
causing the plurality of outlets to enter a closed state;
after the plurality of outlets enter the close state, causing one outlet of the plurality of outlets to enter the opened state;
attempting to communicate with each of the plurality of outlets; and
determining a relative position in the circuit of the one of the plurality of outlets relative to another outlet of the plurality of outlets based on a respective identity of each of the plurality of outlets with which communication was successful.

20. The method of claim 19, further comprising:
repeating the learning procedure until each outlet of the plurality of outlets have been in the opened state; and
after repeating the learning procedure, determining a position in the circuit of each outlet of the plurality of outlets.
